(19) United States
(12) Patent Application Publication
(10) Pub. No.: US 2010/0211725 A1
(43) Pub. Date: Aug. 19, 2010

(54) INFORMATION PROCESSING SYSTEM

(75) Inventors: Hiroyuki Nagashima, Kanagawa (JP); Hiroto Nakai, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/672,083

(22) PCT Filed: Oct. 17, 2008
(86) PCT No.: PCT/JP2008/069287

§ 371 Date: Feb. 4, 2010

(30) Foreign Application Priority Data
Oct. 17, 2007 (JP) 2007-269772

(51) Int. Cl. G06F 12/00; G06F 12/08; G11C 11/00

(52) U.S. Cl. 711/103; 711/105; 365/148; 711/E12.001; 711/E12.008

(57) ABSTRACT

An information processing system comprises a main memory operative to store data, and a control circuit operative to access the main memory for data. The main memory includes a nonvolatile semiconductor memory device containing electrically erasable programmable nonvolatile memory cells each using a variable resistor, and a DRAM arranged as a cache memory between the control circuit and the nonvolatile semiconductor memory device. The nonvolatile semiconductor memory device has a refresh mode of rewriting stored data. The control circuit activates the nonvolatile semiconductor memory device in said refresh mode based on the number of accesses to the nonvolatile semiconductor memory device.

### TECHNICAL FIELD

The present invention relates to an information processing system such as a computer system and a mass-storage card system, and more particularly to an information processing system comprising a nonvolatile semiconductor memory device using a variable resistor as a storage medium.

### BACKGROUND ART

In recent years, computer systems are required to have a mass-storage, high-speed main memory in accordance with developments of various applications to improve performances thereof. The main memory used in the computer system in the art comprises a DRAM in general. The DRAM has a one-transistor/one-cell (1T1C) structure and accordingly has a limit in fine patterning, which makes it difficult to provide a mass-storage main memory.

On the other hand, technologies of pattering memory cells much finer include a resistance variable memory, which uses a variable resistor in a memory cell as proposed (Patent Document 1). The resistance variable memory of such the type utilizes the fact that the resistance ratio of crystal to non-crystal of chalcogenide glass is as large as 100:1 or more, and stores the different resistance states as information. The resistance variable memory may include a serial circuit of a Schottky diode and a variable resistor in place of the transistor to configure a memory cell. Accordingly, it can be easily stacked in layers and three-dimensionally structured to achieve much higher integration as an advantage (Patent Document 2).

It is not assumed that, however, the above-described resistance variable memory is utilized as a frequently accessible main memory and causes problems on high-speed operation and reliability.

### [Patent Document 1] WO 2000/623014

### [Patent Document 2] WO 2003/085675

### DISCLOSURE OF INVENTION

### Technical Problem

The present invention has an object to provide an information processing system capable of ensuring high-speed operation and reliability of a memory device while achieving mass storage.

### Technical Solution

In an aspect the present invention provides an information processing system, comprising: a main memory operative to store data; and a control circuit operative to access the main memory for data, the main memory including a nonvolatile semiconductor memory device containing electrically erasable programmable nonvolatile memory cells each using a variable resistor, and a DRAM arranged as a cache memory between the control circuit and the nonvolatile semiconductor memory device.

In another aspect the present invention provides an information processing system, comprising: a nonvolatile semiconductor memory device containing electrically erasable programmable nonvolatile memory cells each using a variable resistor; and a control circuit operative to access the nonvolatile semiconductor memory device, wherein the nonvolatile semiconductor memory device has a refresh mode of rewriting stored data, wherein the control circuit activates the nonvolatile semiconductor memory device in said refresh mode based on the number of accesses to the nonvolatile semiconductor memory device.

In another aspect the present invention provides an information processing system, comprising: a main memory including a nonvolatile semiconductor memory device containing electrically erasable programmable nonvolatile memory cells each using a variable resistor; and a control circuit operative to access the main memory for data, wherein the nonvolatile semiconductor memory device has a refresh mode of rewriting stored data.

### EFFECT OF THE INVENTION

The present invention makes it possible to ensure high-speed operation and reliability of a memory device while achieving mass storage.

### BRIEF DESCRIPTION OF DRAWINGS

FIG. 1 is a block diagram showing a configuration of a computer system according to a first embodiment of the present invention.

FIG. 2 is a block diagram of a nonvolatile memory in the same embodiment.

FIG. 3 is a perspective view of part of a memory cell array in the nonvolatile memory according to the same embodiment.

FIG. 4 is a cross-sectional view of one memory cell taken along I-I′ line and seen in the direction of the arrow in FIG. 2.

FIG. 5 is a schematic cross-sectional view showing a variable resistor example in the same embodiment.

FIG. 6 is a schematic cross-sectional view showing another variable resistor example in the same embodiment.

FIG. 7 is a schematic cross-sectional view showing a non-ohmic element example in the same embodiment.

FIG. 8 is a perspective view of part of a memory cell array according to another embodiment of the present invention.

FIG. 9 is a cross-sectional view of one memory cell taken along II-II′ line and seen in the direction of the arrow in FIG. 7.

FIG. 10 is a circuit diagram of the memory cell array and peripheral circuits in the nonvolatile memory according to the same embodiment.

FIG. 11 is a graph showing a relation between resistance distributions and data in the memory cell in the case of binary data.

FIG. 12 is a waveform diagram showing word and bit line voltages on write, erase and read operations in the same embodiment.

FIG. 13 is a waveform diagram showing word and bit line voltages on refresh operation in the same embodiment.

FIG. 14 is a waveform diagram showing word and bit line voltages on refresh operation in a second embodiment of the present invention.

FIG. 15 is a block diagram of a memory cell array in the same embodiment.

FIG. 16 is a block diagram showing a configuration of a mass-storage card system according to a third embodiment of the present invention.

FIG. 17 is a block diagram of a memory cell array illustrative of refresh operation according to a fourth embodiment of the present invention.

### BEST MODE FOR CARRYING OUT THE INVENTION

The embodiments of the invention will now be described with reference to the drawings.

### First Embodiment

### Entire Configuration

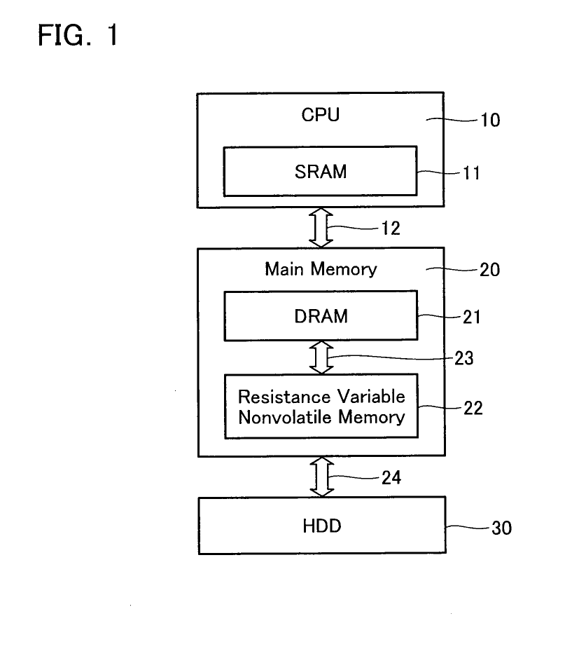

FIG. 1 is a block diagram showing a configuration of an information processing system or a computer system according to a first embodiment of the present invention.

The computer system comprises a CPU (Central Processing Unit) 10, a main memory 20 accessible from the CPU 10, and an external storage device or HDD (Hard Disc Drive) 30 connected to the CPU 10 via the main memory 20. The CPU 10 includes a SRAM 11 operable as an internal cache memory, which is connected to the main memory 20 via a bus 12. The main memory 20 includes a DRAM 21 and a resistance variable nonvolatile memory 22. The DRAM 21 serves as a lower grade cache memory in the computer system and the resistance variable nonvolatile memory 22 serves as a mass storage memory. Both are connected to each other via a high-speed bus 23. The external storage device connected to the main memory 20 via a bus 24 may also include a flexible disc device, a CD-ROM and a DVD other than the HDD 30.

With such the configuration, the CPU 10 makes high-speed access to the DRAM 21 while the resistance variable nonvolatile memory 22 provides mass storage in the main memory 20. A primary, a secondary, a tertiary cache and so forth may be arranged between the CPU 10 and the main memory 20.

### [Configuration of Nonvolatile Memory]

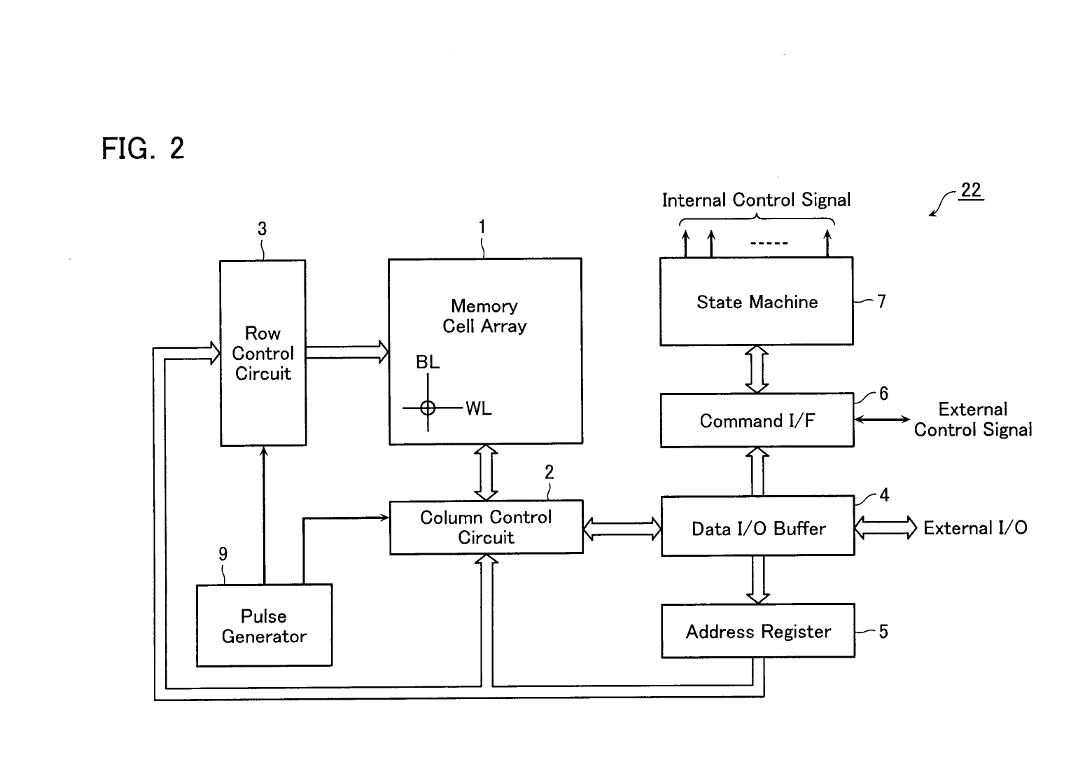

FIG. 2 is a block diagram of the nonvolatile memory 22 for use in the main memory 20.

The nonvolatile memory 22 comprises a memory cell array 1 of memory cells arranged in matrix, each memory cell including a later-described resistance variable element such as a PCRAM (phase change element) and a ReRAM (variable resistor). A column control circuit 2 is provided on a position adjacent to the memory cell array 1 in the bit line BL direction. It controls the bit line BL in the memory cell array 1 to erase data from the memory cell, write data in the memory cell, and read data out of the memory cell. A row control circuit 3 is provided on a position adjacent to the memory cell array 1 in the word line WL direction. It selects the word line WL in the memory cell array 1 and applies voltages required to erase data from the memory cell, write data in the memory cell, and read data out of the memory cell.

A data I/O buffer 4 is connected to the DRAM 21 via the high-speed bus 23 and connected to the CPU 10 via a control bus to receive write data, receive erase instructions, provide read data, and receive address data and command data. The data I/O buffer 4 sends received write data to the column control circuit 2 and receives read-out data from the column control circuit 2 and provides it to external. An address fed from the CPU 10 to the data I/O buffer 4 is sent to the column control circuit 2 and the row control circuit 3 via an address register 5. A command fed from the CPU 10 to the data I/O buffer 4 is sent to a command interface 6. The command interface 6 receives an external control signal from the CPU 10 and decides whether the data fed to the data I/O buffer 4 is write data, a command or an address. If it is a command, then the command interface transfers it as a received command signal to a state machine 7. The state machine 7 manages the entire nonvolatile memory to receive commands from the CPU 10, read, write, erase, and execute data I/O management. The external CPU 10 can also receive status information managed by the state machine 7 and decide the operation result. The status information may also be utilized in control of write and erase.

The state machine 7 controls the pulse generator 9. This control enables the pulse generator 9 to provide pulses at any voltage and timing. The formed pulses can be transferred to any line selected by the column control circuit 2 and the row control circuit 3.

Elements in peripheral circuits other than the memory cell array 1 may be formed in a Si substrate immediately beneath the memory array 1 formed in a wiring layer. Thus, the chip area of the nonvolatile memory can be made almost equal to the area of the memory cell array 1.

### [Memory Cell Array and Peripheral Circuits]

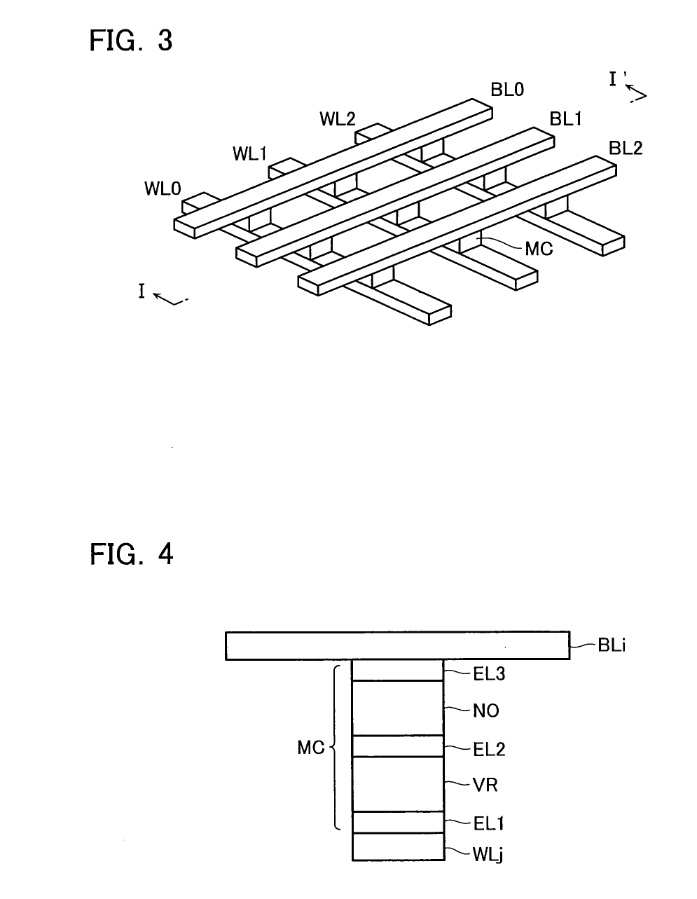

FIG. 3 is a perspective view of part of the memory cell array 1, and FIG. 4 is a cross-sectional view of one memory cell taken along I-I′ line and seen in the direction of the arrow in FIG. 3.

There are plural first lines or word lines WL0-WL2 disposed in parallel, which cross plural second lines or bit lines BL0-BL2 disposed in parallel. A memory cell MC is arranged at each intersection of both lines and sandwiched therebetween. Desirably, the first and second lines are composed of heat-resistive low-resistance material such as W, WSi, NiSi, CoSi.

The memory cell MC comprises a serial connection circuit of a variable resistor VR and a non-ohmic element NO as shown in FIG. 4.

The variable resistor VR can vary the resistance through current, heat, or chemical energy on voltage application. Arranged on an upper and a lower surface thereof are electrodes EL1, EL2 serving as a barrier metal layer and an adhesive layer. Material of the electrodes may include Pt, Au, Ag, TiAlN, SrRuO, Ru, RuN, Ir, Co, Ti, TiN, TaN, LaNiO, Al, PtIrOx, PtRhOx, Rh/TaAlN, TiOx, NbTiOx, Si. A metal film capable of achieving uniform orientation may also be interposed. A buffer layer, a barrier metal layer and an adhesive layer may further be interposed.

The variable resistor VR may include one such as chalcogenide that varies the resistance through the phase change between the crystal state and the non-crystal state (PCRAM); one that varies the resistance through precipitation of metal cations to form a bridge (conducting bridge) between electrodes or ionize the precipitated metal to break the bridge (CBRAM); and one that varies the resistance through voltage or current application (ReRAM) (which is roughly divided into one that causes a resistance variation in response to the presence/absence of charge trapped in a charge trap present in an electrode interface, and one that causes a resistance variation in response to the presence/absence of a conduction path due to a loss in oxygen).

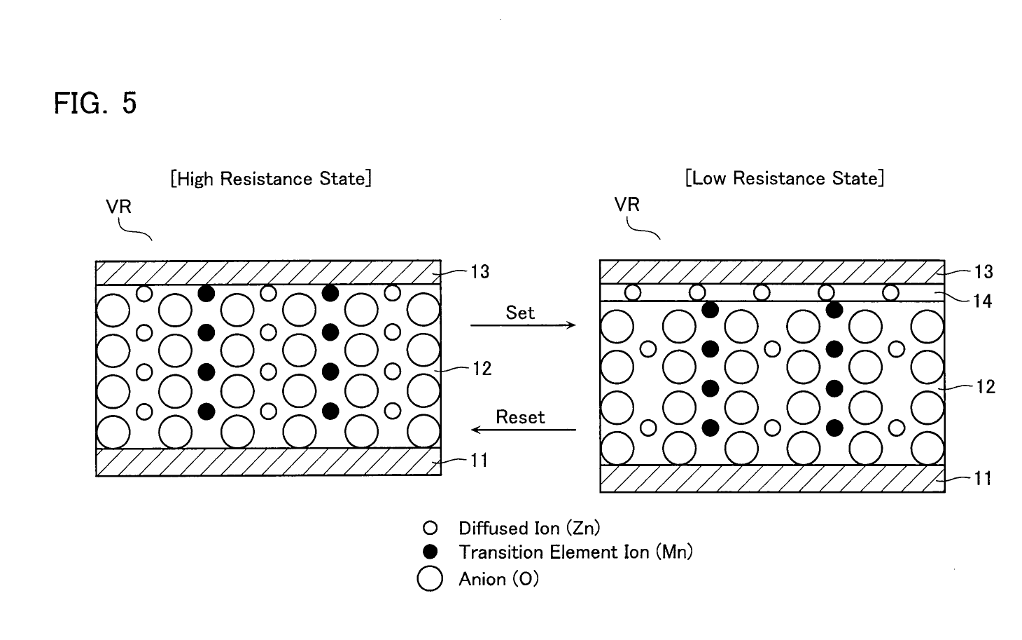

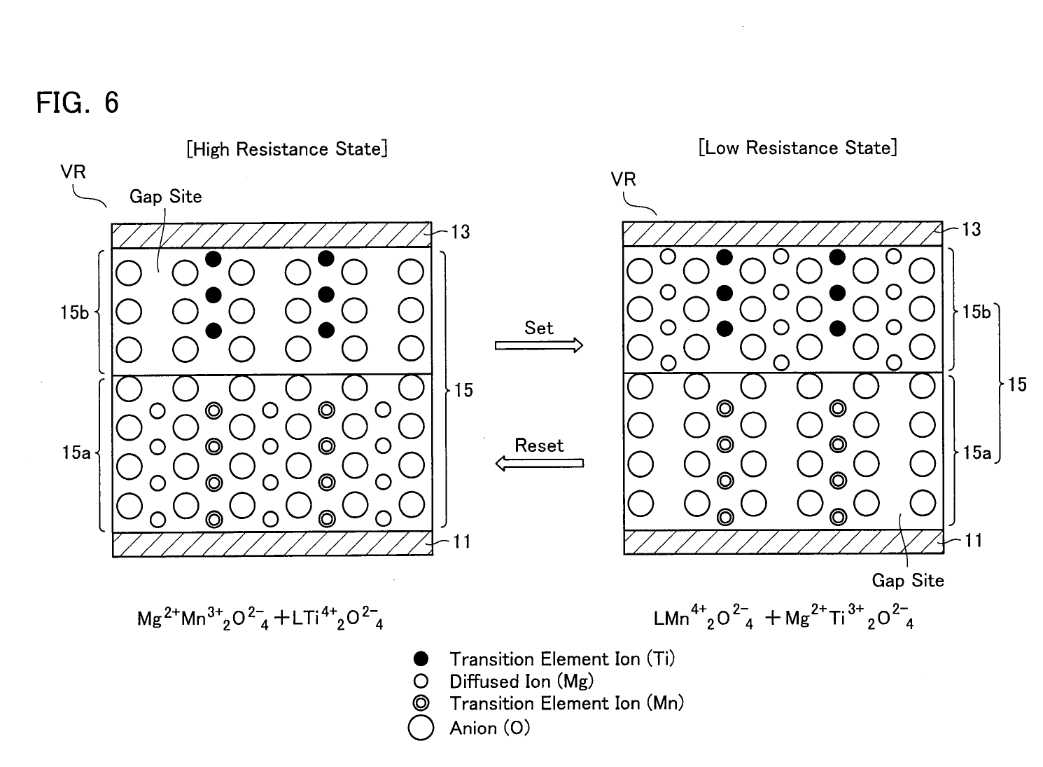

FIGS. 5 and 6 show examples of the latter variable resistor. The variable resistor VR shown in FIG. 5 includes a recording layer 12 arranged between electrode layers 11, 13. The recording layer 12 is composed of a composite compound containing at least two types of cation elements. At least one of the cation elements is a transition element having the d-orbit incompletely filled with electrons, and the shortest distance between adjacent cation elements is 0.32 nm or lower. Specifically, it is represented by a chemical formula AₓM_{y}X_{z} (A and M are different elements) and may be formed of material having a crystal structure such as a spinel structure (AM₂O₄), an ilmenite structure (AMO₃), a delafossite structure (AMO₂), a LiMoN₂ structure (AMN₂), a wolframite structure (AMO₄, an olivine structure (A₂MO₄), a hollandite structure (AMO₂), a ramsdellite structure (AₓMO₂), and a perovskite structure (AMO₃).

In the example of FIG. 5, A comprises Zn, M comprises Mn, and X comprises O. In the recording layer 12, a small white circle represents a diffused ion (Zn), a large white circle represents an anion (O), and a small black circle represents a transition element ion (Mn). The initial state of the recording layer 12 is the high-resistance state. When the electrode layer 11 is kept at a fixed potential and a negative voltage is applied to the electrode layer 13, part of diffused ions in the recording layer 12 migrate toward the electrode layer 13 to reduce diffused ions in the recording layer 12 relative to anions. The diffused ions arrived at the electrode layer 13 accept electrons from the electrode layer 13 and precipitate as a metal, thereby forming a metal layer 14. Inside the recording layer 12, anions become excessive and consequently increase the valence of the transition element ion in the recording layer 12. As a result, the carrier injection brings the recording layer 12 into electron conduction and thus completes setting. On regeneration, a current may be allowed to flow, of which value is very small so that the material configuring the recording layer causes no resistance variation. The programmed state (low-resistance state) may be reset to the initial state (high-resistance state) by supplying a large current flow in the recording layer 12 for a sufficient time, which causes Joule heating to facilitate the oxidation reduction reaction in the recording layer 12. Application of an electric field in the opposite direction from that at the time of setting may also allow resetting.

In the example of FIG. 6, a recording layer 15 sandwiched between the electrode layers 11, 13 is formed of two layers: a first compound layer 15a and a second compound layer 15b. The first compound layer 15a is arranged on the side close to the electrode layer 11 and represented by a chemical formula AₓM1_{y}X1_{z}. The second compound layer 15b is arranged on the side close to the electrode layer 13 and has gap sites capable of accommodating cation elements from the first compound layer 15a.

In the example of FIG. 6, in the first compound layer 15a, A comprises Mg, M1 comprises Mn, and X1 comprises O. The second compound layer 15b contains Ti shown with black circles as transition reduction ions. In the first compound layer 15a, a small white circle represents a diffused ion (Mg), a large white circle represents an anion (O), and a double circle represents a transition element ion (Mn). The first compound layer 15a and the second compound layer 15b may be stacked in multiple layers such as two or more layers.

In such the variable resistor VR, potentials are given to the electrode layers 11, 13 so that the first compound layer 15a serves as an anode and the second compound layer 15b serves as a cathode to cause a potential gradient in the recording layer 15. In this case, part of diffused ions in the first compound layer 15a migrate through the crystal and enter the second compound layer 15b on the cathode side. The crystal of the second compound layer 15b includes gap sites capable of accommodating diffused ions. Accordingly, the diffused ions moved from the first compound layer 15a are trapped in the gap sites. Therefore, the valence of the transition element ion in the first compound layer 15a increases while the valence of the transition element ion in the second compound layer 15b decreases. In the initial state, the first and second compound layers 15a, 15b may be in the high-resistance state. In such the case, migration of part of diffused ions in the first compound layer 15a therefrom into the second compound layer 15b generates conduction carriers in the crystals of the first and second compounds, and thus both have electric conduction. The programmed state (low-resistance state) may be reset to the erased state (high-resistance state) by supplying a large current flow in the recording layer 15 for a sufficient time for Joule heating to facilitate the oxidation reduction reaction in the recording layer 15, like in the preceding example. Application of an electric field in the opposite direction from that at the time of setting may also allow reset.

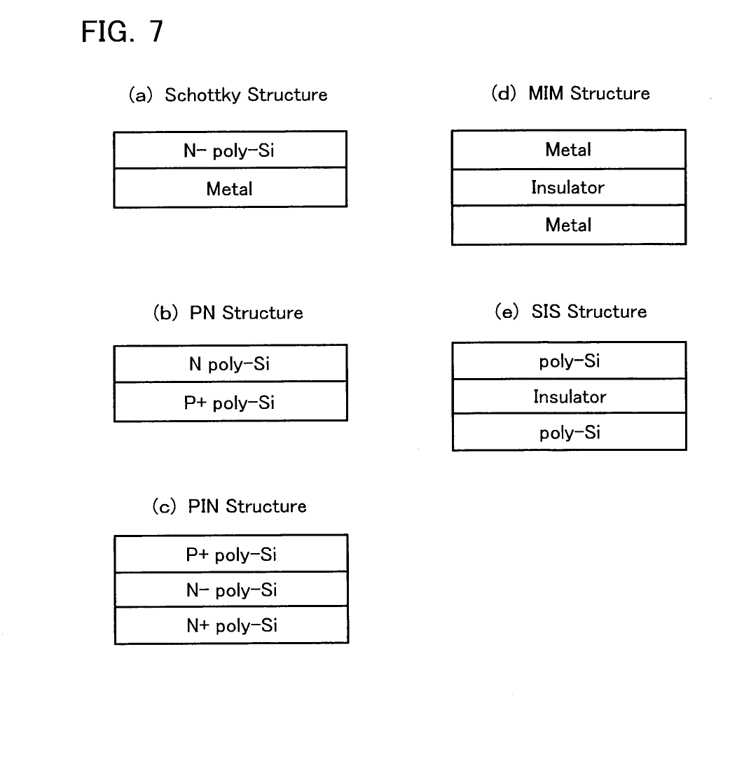

The non-ohmic element NO may include various diodes such as (a) a Schottky diode, (b) a PN-junction diode, (c) a PIN diode and may have (d) a MIM (Metal-Insulator-Metal) structure, and (e) a SIS (Silicon-Insulator-Silicon) structure as shown in FIG. 7. In this case, electrodes EL2, EL3 forming a barrier metal layer and an adhesive layer may be interposed. If a diode is used, from the property thereof, it can perform the unipolar operation. In the case of the MIM structure or SIS structure, it can perform the bipolar operation. The non-ohmic element NO and the variable resistor VR may be arranged in the opposite up/down relation from FIG. 4. Alternatively, the non-ohmic element NO may have the up/down-inverted polarity.

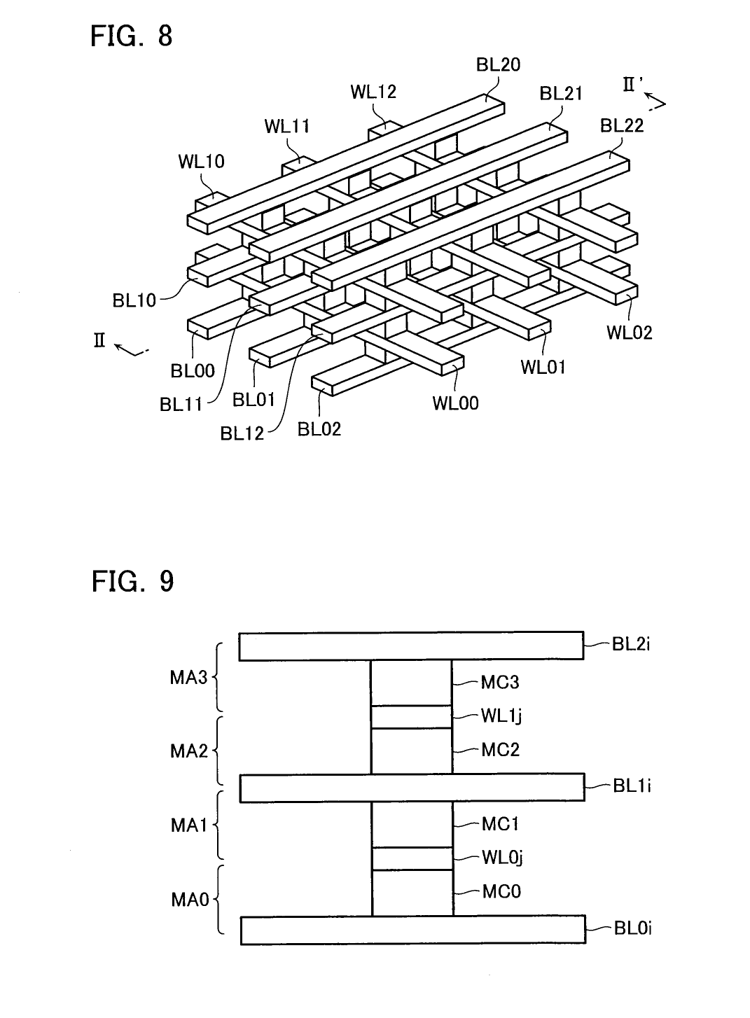

Plural such memory structures described above may be stacked to form a three-dimensional structure as shown in FIG. 8. FIG. 9 is a cross-sectional view showing an II-II′ section in FIG. 8. The shown example relates to a memory cell array of a 4-layer structure having cell array layers MA0-MA3. A word line WL0j is shared by an upper and a lower memory cell MC0, MC1. A bit line BL1i is shared by an upper and a lower memory cell MC1, MC2. A word line WL1j is shared by an upper and a lower memory cell MC2, MC3. In place of the line/cell/line/cell repetition, an interlayer insulator may be interposed as a line/cell/line/interlayer-insulator/line/cell/line between cell array layers.

The memory cell array 1 may be divided into MATs of several memory cell groups. The column control circuit 2 and the row control circuit 3 described above may be provided on a MAT-basis, a sector-basis, or a cell array layer MA-basis or shared by them. Alternatively, they may be shared by plural bit lines BL to reduce the area.

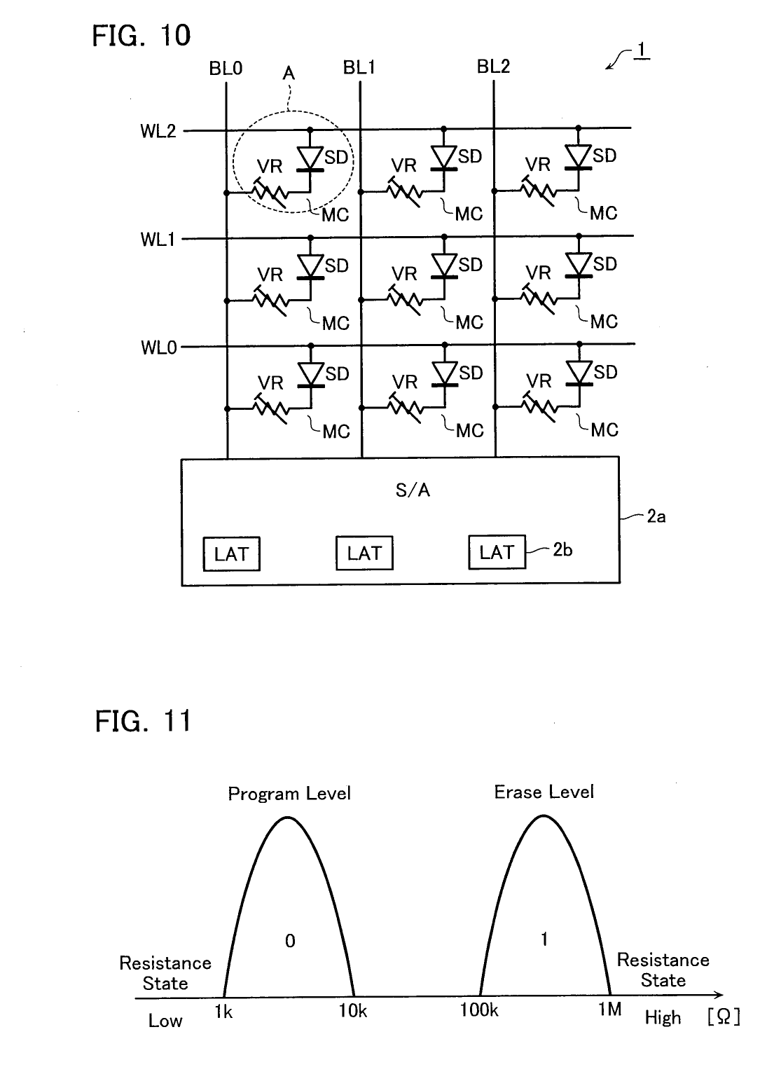

FIG. 10 is circuit diagram of the memory cell array 1 using a diode SD as the non-ohmic element NO and peripheral circuits. For simplicity, the description advances on the assumption that the memory has a single-layered structure.

In FIG. 10, the diode contained in the memory cell MC has an anode connected to the word line WL and a cathode connected to the bit line BL via the variable resistor VR. Each bit line BL has one end connected to a sense amplifier 2a, which is part of the column control circuit 2. The sense amplifier 2a includes a latch 2b operative to store data to be written in a selected memory cell MC connected to the bit line BL or data read out of the selected memory cell MC. Each word line WL has one end connected to the row control circuit 3.

The memory cell MC may be selected individually. Alternatively, plural memory cells MC connected to the selected word line WL1 may be batch read for data. In the memory cell array 1, the diode SD is connected opposite in polarity than the circuit shown in FIG. 10 such that current can flow from the bit line BL to the word line WL.

### [Operation of Nonvolatile Memory]

The following description is given to operation of the nonvolatile semiconductor memory in the computer system thus configured.

The variable resistor VR contained in the memory cell MC has a resistance, which distributes within a high-resistance range of from 100 kΩ to 1 MΩ in the erased state and within a low-resistance range of from 1 kΩ to 10 kΩ in the written (programmed) state. Write is a process with application of a certain write voltage Vprog to the variable resistor VR in the erased state to shift the resistance of the variable resistor VR into the low-resistance range.

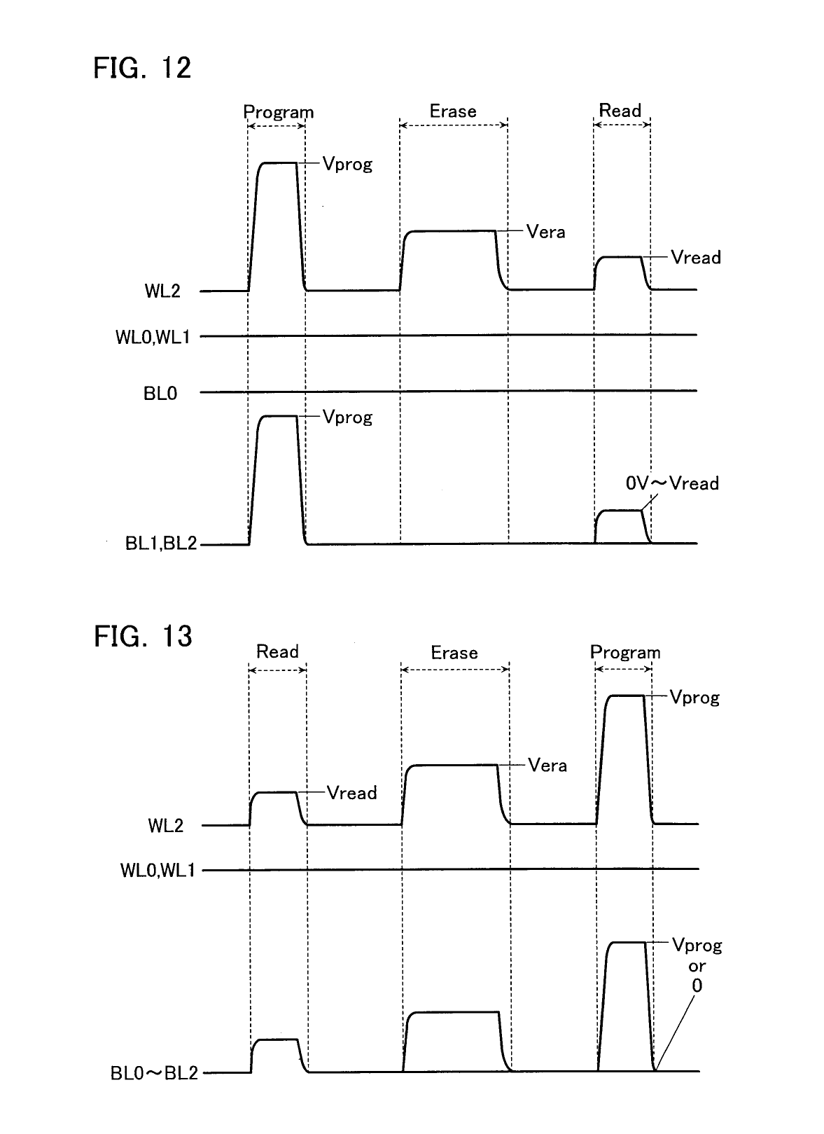

It is assumed now that data is written (programmed) in a selected cell A or a memory cell MC connected to a word line WL2 and a bit line BL0, as shown with a dotted-line circle in FIG. 10. In this case, the write voltage Vprog is applied to the selected word line WL2, and 0 V is applied to non-selected word lines WL0, WL1 as shown in FIG. 12. In addition, 0 V is applied to the selected bit line BL0 and the write voltage Vprog is applied to non-selected bit lines BL1, BL2. As a result, the variable resistor VR in the selected cell A is forward-biased with application of the write voltage Vprog and the resistance of the variable resistor VR shifts from the high-resistance distribution to the low-resistance distribution.

When memory cells MC connected to the word line WL2, containing the selected cell A, are to be batch erased, an erase voltage Vera is applied to the selected word line WL2, and 0 V is applied to non-selected word lines WL0, WL1 as shown in FIG. 12. In addition, 0 V is applied to the selected bit lines BL0-BL2. When the written cell is erased, a lower voltage is applied as the erase voltage Vera for a longer time than the program voltage Vprog because the written cell is in the low-resistance state. When larger current flows in the variable resistor VR in the low-resistance state for a longer time in this way, Joule heat resets the variable resistor VR to the high-resistance state. Thus, the memory cells MC connected to the selected word line WL2 can be batch erased.

When data is read out of the selected cell A, a voltage Vread is applied to the selected word line WL2, and 0 V is applied to non-selected word lines WL0, WL1 as shown in FIG. 12. In addition, 0 V is applied to the selected bit line BL0 while 0 V to Vread is applied to non-selected bit lines BL1, BL2. Thus, the diode in the selected cell A is forward-biased and accordingly a voltage of almost Vread is applied to the selected cell A. In this case, the current flowing in the cell exhibits a variation depending on whether the cell resistance is a high resistance or a low resistance. Accordingly, the variation can be sensed at the sense amplifier 2a to read out data.

The read voltage Vread must be lower than the write voltage Vprog and the erase voltage Vera. On the other hand, as for non-selected cells, the non-selected cells connected to the word line WL2 are supplied with Vread on the side close to the word line WL2. In this case, if 0 V is applied to the bit lines BL1, BL2, the memory cells MC connected to the bit lines BL1, BL2 are brought into the read state similar to the selected cell A, which makes plural cells readable. If Vread is given to the bit lines BL1, BL2, any voltage stress is not placed effectively on the cells connected to the bit lines BL1, BL2 (nor any current flows). In addition, as for the cells connected to the word lines WL0, WL1, any voltage stress is not placed (nor any current flows) if the bit lines BL0-BL2 are at 0 V because the word lines WL0, WL1 are at 0 V. Even if the bit lines BL1, BL2 are given Vread, non-selected cells connected to the bit lines BL1, BL2 are reverse-biased with the diode SD. Therefore, less voltage stress is placed on the cell and less current flows therein. Further, non-selected bit lines BL1, BL2 can be given a voltage between 0 and Vread. This is effective to suppress the application of the reverse bias voltage to non-selected cells. As described above, the cells may be read on a 1-bit basis or all cells connected to one word line WL may be batch read.

Read operation can be executed as described above though Read Disturb (RD) may be concerned depending on the read condition at that time. In the case of a selected cell, a read bias voltage Vread is applied to the cell. In the case of a non-selected cell, a reverse bias voltage is applied to the diode, possibly placing a stress thereon. In order to use the nonvolatile semiconductor memory 22 in the main memory 20, it is expected not to cause data garbled even after read operations are repeated 10⁶ times or more. A systematic solution therefor is shown below.

In FIG. 1, the CPU 10 makes access to the main memory 20 to issue a data read request to the main memory 20. Based on this request, the main memory 20 reads out data and transfers it to the CPU 10. In practice, data is read out of the resistance-variable nonvolatile semiconductor memory 22 and the read data is transferred to the DRAM 21 and the CPU 10. In this case, RD may be concerned in the resistance-variable nonvolatile semiconductor memory 22. Namely, as described above, the read voltage Vread is applied to the selected cell and accordingly a weak stress is placed on it. The voltage value of the read voltage Vread has no large difference from the voltage value of the erase voltage Vera. Therefore, after read operations are repeated several times, the cell in the programmed state gradually shifts to the erased state and finally leads to data garbled as a possible problem.

Therefore, in this embodiment, the CPU 10 issues refresh instructions to the resistance-variable nonvolatile semiconductor memory 22. The frequency of issuing refresh instructions may be set arbitrarily. For example, the refresh instructions may be provided once relative to 1,000 times of read operation or once relative to 10,000 times of read operation. The frequency of executing refresh instructions may be switched between that immediately after the beginning of the use and that when the number of write/erase operations exceeds a certain number. On reception of the refresh instruction as above, the resistance-variable nonvolatile semiconductor memory 22 starts refresh operation.

A refresh target area may be determined on the basis of information on a FAT (File Allocation Table) region. The information may be held in the resistance-variable nonvolatile semiconductor memory 22 itself.

In an example, refresh operation is executed as shown in FIG. 13. First, data is read out. Namely, the read voltage Vread is applied to the selected word line WL2, and 0 V is applied to non-selected word lines WL0, WL1 as shown in FIG. 13. In addition, 0 V is applied to bit lines BL0-BL2. A read operation on a page (WL) basis is desirable though plural MATs may be batch read if the memory cell array 1 is divided into MATs. The read data is saved at the latch circuit 2b in the sense amplifier 2a.

Next, erase operation is executed. Namely, the read voltage Vera is applied to the selected word line WL2, and 0 V is applied to non-selected word lines WL0, WL1 as shown in FIG. 13. In addition, 0 V is applied to bit lines BL0-BL2. As a result, data in the selected cell can be erased and data in non-selected cells can not be erased. Thus, the erase operation may be executed on a page basis in batch or may be executed over plural MATs in batch. Moreover, data in MAT0 may be erased on 1-bit, plural bits, or 1-page basis according to power consumption.

Thereafter, the read data initially read out and saved in the latch circuit 2b is written back again to the cell. This write operation is also executed on a page basis. In this case, the write voltage Vprog is applied to the selected word line WL2, and 0 V is applied to non-selected word lines WL0, WL2 as shown in FIG. 13. In addition, the read data is set on the bit lines BL0-BL2. If the read data is in the erased state, then the write voltage Vprog is applied to the bit line BL. If it is in the written state, then 0 V is applied to the bit line BL. This bias relation enables execution of programming on a page basis in batch.

Thus, the refresh operation associated with the word line WL2 in the nonvolatile semiconductor memory 22 is finished. This operation is repeatedly executed over any refresh-intended areas to finish the refresh operation. As a result, the stress caused by the read bias during multiple times of reading can be restored to zero, which can improve the reliability against RD.

In addition, the data in the latch circuit 2b can be rewrited by designating address and inputting data from the external I/O via the data I/O buffer 4. Therefore, the refresh operation can also be executed by returning to the latch circuit 2b the data read and ECC-corrected in the CPU 10.

### Second Embodiment

In the above first embodiment, a refresh operation is executed through page-based read, erase and write in turn. In this case, it is just required to completely rewrite data in the original storage place and not required to alternate the FAT.

On the contrary, in the present embodiment, data is once copied into another area to execute refresh operation.

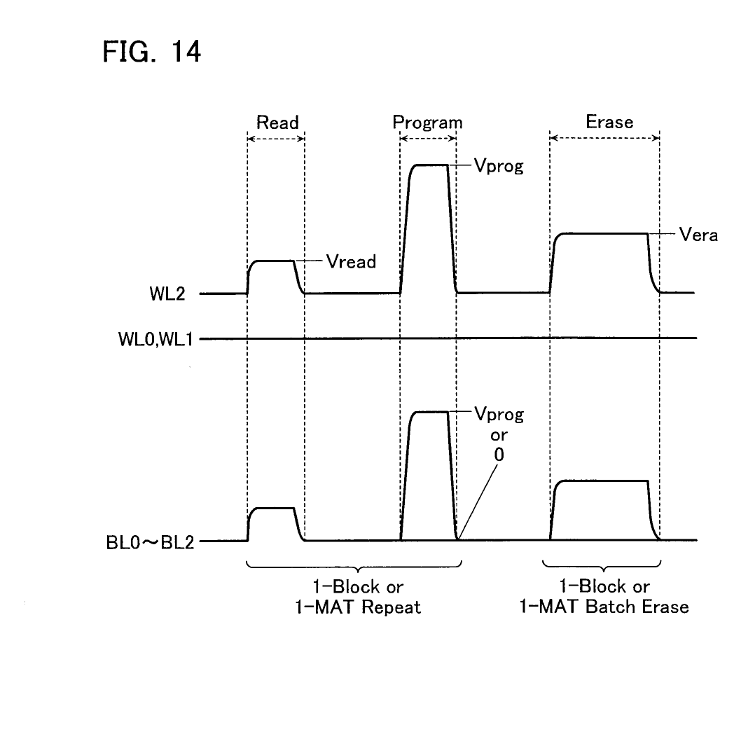

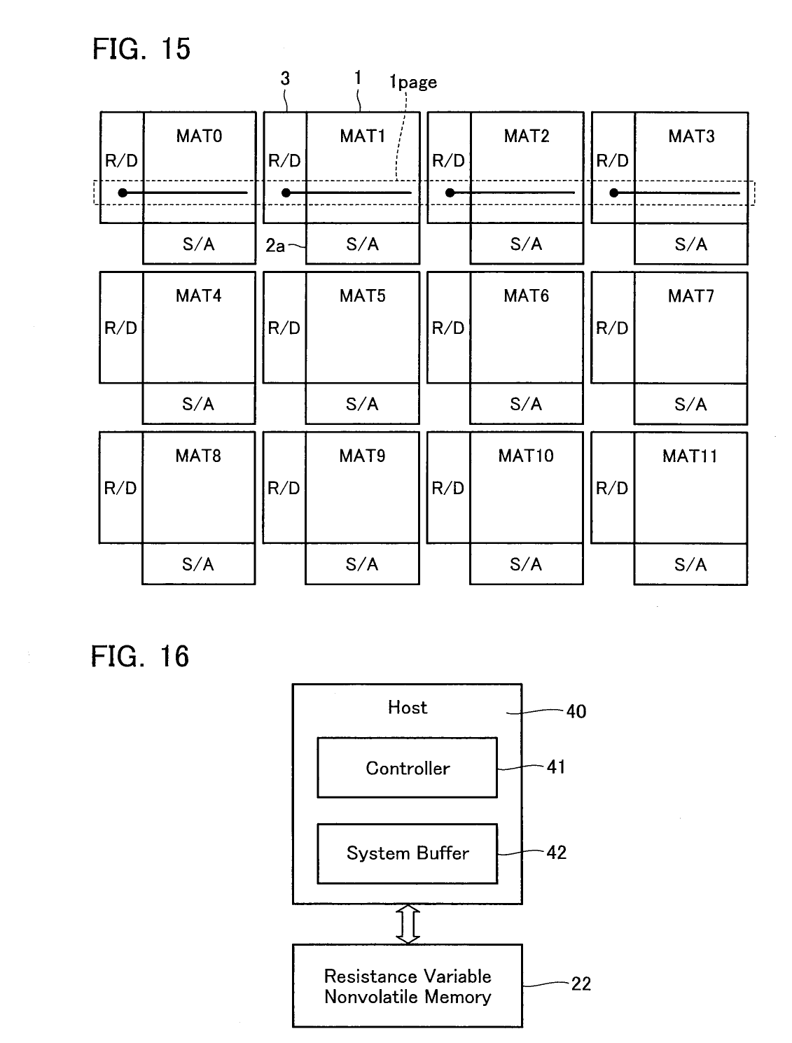

The refresh operation in the present embodiment is shown in FIG. 14. A copy operation is herein used in refresh. Accordingly, the memory cell array 1 is divided into plural MATs (or blocks) as shown in FIG. 15. Each MAT includes a row control circuit 3 and a sense amplifier 2a for making independent access thereto. The MAT is copied to other MATs to refresh data.

First, read operation is executed as shown in FIG. 14. For example, data is read out of MAT0 by one page. One page of data stored in MAT0 is read out to the sense amplifier 2a and latched at the latch circuit 2b. Thereafter, the data is written in MAT4. MAT0 and MAT4 may share the sense amplifier 2a. In such the case, the data read out of MAT0 can be transferred to the bit line BL in MAT4 without the need for a transfer circuit or the like. Thus, the read data can be written as it is. Moreover, the read data ECC-corrected in the CPU 10 may be written in a memory cell. In addition, MAT0 and MAT1 may share the sense amplifier 2a. In the case of a multi-layered cross-point memory cell arrays, MATs of memory cell arrays in an upper and a lower layer may share one sense amplifier (not shown). When the above operation is executed over the entire page in MAT, data in MAT0 is all copied to MAT4.

Finally, data in MAT0 is batch erased as shown in FIG. 14. Namely, in MAT0 the erase voltage Vera is applied to all word lines WL and 0 V is applied to all bit lines BL, thereby enabling batch erase of one MAT. Thereafter, management data on the FAT region is rewritten to finish the refresh operation.

### Third Embodiment

FIG. 16 is a block diagram showing a configuration of a mass-storage card system according to a third embodiment of the present embodiment. In the preceding embodiments, the resistance-variable nonvolatile semiconductor memory 22 is used as the main memory 20 in the computer system and the refresh instruction is issued from the CPU 10 in the computer system.

On the contrary, in this embodiment, a host device 40 is provided in the mass-storage card system that uses the resistance-variable nonvolatile semiconductor memory 22 as a mass-storage memory card. The host device 40 includes a controller 41 and a system buffer therein and controls access to the resistance-variable nonvolatile semiconductor memory 22. Therefore, the controller 41 in the host device 40 internally issues the refresh instruction, thereby enabling voluntary refresh operation inside the mass-storage card system or the memory alone.

### Fourth Embodiment

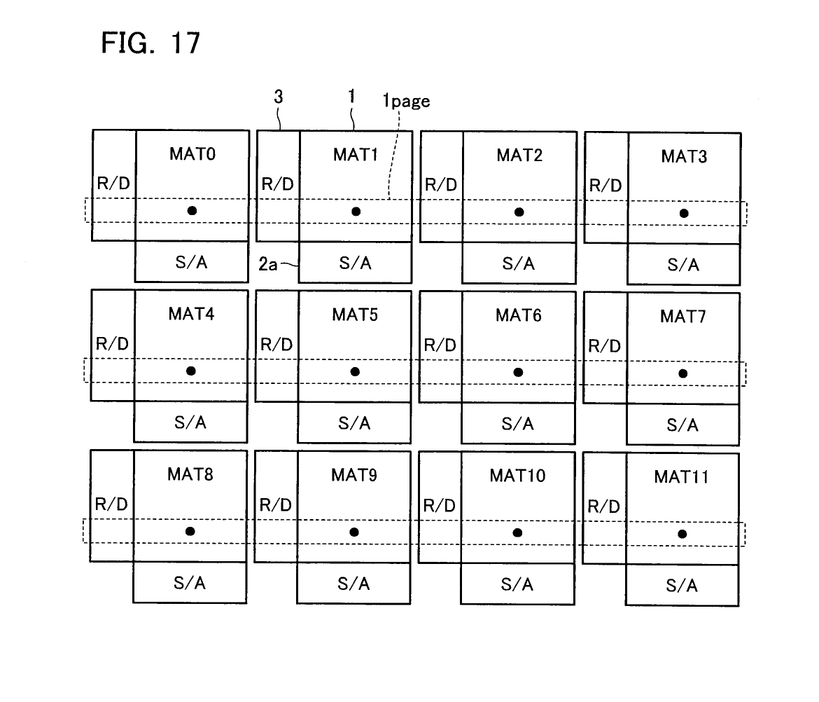

FIG. 17 shows a configuration of a memory illustrative of refresh operation in a nonvolatile semiconductor memory device according to a fourth embodiment of the present invention.

In this embodiment, memory cells are divided into plural independently accessible cell array units (MATs) and one-cell data is read out of each cell array unit in unison. In accordance with the read data, the associated cells are accessed for program (overwrite) or erase in unison, thereby executing refresh.

Namely, each MAT is accessed for one bit and all MATs are accessed in parallel as in an assumed form. In this case, at the time of data write, individual write or erase can be executed on a MAT basis in accordance with input data to each MAT. Therefore, if the input data is “0”, then a write (set) pulse is transferred to the row control circuit 3. If the input data is “1”, then an erase (reset) pulse is transferred to the row control circuit 3. Such the operation can be executed over all MATs in unison to execute batch write or batch erase to all MATs in parallel at the same time.

In execution of refresh operation with the use of such the access scheme, pieces of data are read out of all MATs first, and saved at the latch circuits 2b in the sense amplifiers 2a. Then, the pieces of data are used to overwrite the MATs. Namely, if the read data is “0”, then a write pulse is transferred to the row control circuit 3. If the read data is “1”, then an erase pulse is transferred to the row control circuit 3. Such the operation can be executed in unison to refresh both the cells in the set state and the cells in the reset state at the same time. Therefore, the refresh time can be made shorter than that in the preceding embodiments.

In addition, the data in the latch circuit 2b may be rewrited by designating address and inputting data from the external I/O via the data I/O buffer 4. Therefore, the refresh operation may also be executed by returning the latch circuit 2b the data read and ECC-corrected in the CPU 10 or the controller 41.

### Fifth Embodiment

The increase in the main memory elevates the possibility of causing a failure in memory cells.

Therefore, an information processing system according to the present embodiment executes error checking and correction of read data utilizing ECC (Error Checking Code) in the CPU 10 at the time of data read. As a result, the reliability of the information processing system can be improved. Further, if an error is detected, a refresh instruction can be issued for the associated page or memory cell.

Whether refresh is executed on a page basis or on a memory cell basis may be determined on the basis of the number of corrected bits. For example, in the case of the use of 4-bit ECC, if the number of corrected bits is equal to 2 bits or more, the ECC-corrected page can be refreshed. If the number of corrected bit is equal to 1 bit or less, a memory cell can be refreshed.

Regardless of the number of corrected bits, the ECC-corrected memory cell may be refreshed individually.

The present embodiment is applicable to the first through fourth embodiments.

1. An information processing system, comprising:
a main memory operative to store data; and
a control circuit operative to access said main memory for data, said main memory including
a nonvolatile semiconductor memory device containing electrically erasable programmable nonvolatile memory cells each using a variable resistor, and
a DRAM arranged as a cache memory between said control circuit and said nonvolatile semiconductor memory device.

2. The information processing system according to claim 1, wherein
said nonvolatile semiconductor memory device has a refresh mode of rewriting stored data,
said control circuit activates said nonvolatile semiconductor memory device in said refresh mode based on the number of accesses to said nonvolatile semiconductor memory device.

3. The information processing system according to claim 1, wherein
said nonvolatile semiconductor memory device has a refresh mode of rewriting stored data,
said control circuit activates said nonvolatile semiconductor memory device in said refresh mode based on information about a FAT region.

4. The information processing system according to claim 1, wherein
said nonvolatile semiconductor memory device has an ECC function of error checking and correction and a refresh mode of rewriting stored data,
said control circuit activates said nonvolatile semiconductor memory device in said refresh mode if an error is corrected based on a data error checking and correction result in data read.

5. The information processing system according to claim 2, wherein
the number of accesses to said nonvolatile semiconductor memory device is stored in said nonvolatile semiconductor memory device.

6. The information processing system according to claim 2, wherein
said nonvolatile semiconductor memory device is operative in said refresh mode to batch read data out of a specific area, erase data from said specific area after reading said data, and rewrite said read data into said erased specific area.

7. The information processing system according to claim 2, wherein
said nonvolatile semiconductor memory device is operative in said refresh mode to batch read data out of a specific area, write said read data into another specific area, and erase data from said specific area after reading said data.

8. The information processing system according to claim 6, wherein
said nonvolatile semiconductor memory device comprises a plurality of cell array units each including a certain number of individually accessible memory cells,
said specific area includes a certain number of memory cells selected per said cell array unit.

9. The information processing system according to claim 7, wherein
said nonvolatile semiconductor memory device comprises a plurality of cell array units each including a certain number of individually accessible memory cells,
said specific area includes a certain number of memory cells selected per said cell array unit.

10. An information processing system, comprising:
a nonvolatile semiconductor memory device containing electrically erasable programmable nonvolatile memory cells each using a variable resistor; and
a control circuit operative to access said nonvolatile semiconductor memory device,
wherein said nonvolatile semiconductor memory device has a refresh mode of rewriting stored data,
said control circuit activates said nonvolatile semiconductor memory device in said refresh mode based on the number of accesses to said nonvolatile semiconductor memory device.

11. The information processing system according to claim 10, wherein
the number of accesses to said nonvolatile semiconductor memory device is stored in said nonvolatile semiconductor memory device.

12. The information processing system according to claim 10, wherein
said nonvolatile semiconductor memory device is operative in said refresh mode to batch read data out of a specific area, erase data from said specific area after reading said data, and rewrite said read data into said erased specific area.

13. The information processing system according to claim 10, wherein
said nonvolatile semiconductor memory device is operative in said refresh mode to batch read data out of a specific area, write said read data into another specific area, and erase data from said specific area after reading said data.

14. The information processing system according to claim 12, wherein
said nonvolatile semiconductor memory device comprises a plurality of cell array units each including a certain number of individually accessible memory cells,
said specific area includes a certain number of memory cells selected per said cell array unit.

15. The information processing system according to claim 13, wherein
said nonvolatile semiconductor memory device comprises a plurality of cell array units each including a certain number of individually accessible memory cells,
said specific area includes a certain number of memory cells selected per said cell array unit.

16. An information processing system, comprising:
a main memory including a nonvolatile semiconductor memory device containing electrically erasable programmable nonvolatile memory cells each using a variable resistor; and
a control circuit operative to access said main memory for data,
wherein said nonvolatile semiconductor memory device has a refresh mode of rewriting stored data.

17. The information processing system according to claim 16, wherein
said control circuit activates said nonvolatile semiconductor memory device in said refresh mode based on the number of accesses to said nonvolatile semiconductor memory device.

18. The information processing system according to claim 16, wherein
the number of accesses to said nonvolatile semiconductor memory device is stored in said nonvolatile semiconductor memory device.

19. The information processing system according to claim 16, wherein
said nonvolatile semiconductor memory device is operative in said refresh mode to batch read data out of a specific area, write said read data into another specific area, and erase data from said specific area after reading said data.

20. The information processing system according to claim 16, wherein
said nonvolatile semiconductor memory device comprises a plurality of cell array units each including a certain number of individually accessible memory cells.
